(19) United States
(12) Patent Application Publication
(10) Pub. No.: US 2026/0256017 A1
(43) Pub. Date: Aug. 27, 2026

(54) STRUCTURE AND METHOD FOR EMBEDDING A PLURALITY OF DEVICES AND COMPONENTS INTO A SUBSTRATE CORE

(71) Applicant: Advanced Micro Devices, Inc., Santa Clara, CA (US)

(72) Inventor: Kong Toon NG, Hsinchu (TW)

(21) Appl. No.: 19/065,838

(22) Filed: Feb. 27, 2025

(51) Int. Cl. H01L 23/31; H01L 21/56; H01L 23/18; H01L 23/367; H01L 23/498

(52) U.S. Cl. CPC H10W 74/124; H10W 40/228; H10W 74/016; H10W 76/42; H10W 90/701

(57) ABSTRACT

An integrated circuit (IC) module having plurality of devices embedded into a substrate core is provided, along with electronic devices and chip packages having the same. Also provided are method for fabricating the IC module. In one example, the IC module includes a substrate core, an interposer, a plurality of devices, and a molded encapsulation material. The substrate core includes a first face, a second face, and a cavity formed in the substrate core. The cavity is open through the first and second faces of the substrate core. The interposer is disposed in the cavity and has a first face oriented in a common direction with the first surface. The plurality of devices are disposed in the cavity and mounted on a second face of the interposer. The molded encapsulation material is disposed in the cavity and encapsulates the plurality of devices against the second face of the interposer.

### TECHNICAL FIELD

Embodiments of the present disclosure generally relate to embedding a plurality of devices and components into a substrate core, and in particular, to clustering multiple devices and components into a cavity extending through the substrate core.

### BACKGROUND

Power management (PM) device(s) embedded in a substrate core presents a significant advantage to the integrity of power devices of an integrated circuit (IC). This is especially true for power hungry computing devices used in machine learning and artificial intelligence applications. However, such IC packages are typically large and require a thick substrate core of greater than one millimeter in thickness (currently typically at 1.6 millimeters) to ensure IC package warpage requirements and reliability meet industry standards. Embedding PM devices in a thick core have many challenges, such as filling the gaps between the cavity and the embedded power device(s)/component(s). Current embedded power devices may have a thickness around 800 micrometers which requires an increase in the thickness of the device/component structure to match the substrate core thickness, e.g., about 1.6 millimeters. In addition, a large number of cavities, individual cavities for each device/component, in the substrate complicate the cavity formation process and reduce the number of plated through hole vias areas available. The structural integrity of the substrate core may be degraded because of the large number of cavities required in the thick substrate core.

### SUMMARY

In one example, an integrated circuit (IC) module having plurality of devices embedded into a substrate core is provided. The IC module includes a substrate core, an interposer, a plurality of devices, and a molded encapsulation material. The substrate core includes a first face, a second face, and a cavity formed in the substrate core. The cavity is open through the first and second faces of the substrate core. The interposer is disposed in the cavity and has a first face oriented in a common direction with the first surface. The plurality of devices are disposed in the cavity and mounted on a second face of the interposer. The molded encapsulation material is disposed in the cavity and encapsulates the plurality of devices against the second face of the interposer.

In another example, a method for fabricating an integrated circuit module is provided. The method includes electrically and mechanically mounting a plurality of devices on an interposer; encapsulating the plurality of devices mounted on the interposer with a molded encapsulation material to form an assembly; inserting the assembly in a cavity extending completely through a substrate core; and securing the assembly in the cavity.

In yet another example, a system in a package (SiP) having at least one integrated circuit (IC) module is provided. The SiP includes a printed circuit board, a chip package, and a power management module. The printed circuit board has a first surface and a second surface. The chip package is coupled to the first surface of the printed circuit board. The chip package has an integrated circuit (IC) mounted on a substrate. The power management module is mounted to the second surface of the printed circuit board. The power management module includes a substrate core, an interposer, a plurality of devices, and a molded encapsulation material. The substrate core includes a first face, a second face, and a cavity formed in the substrate core. The cavity is open through the first and second faces of the substrate core. The interposer is disposed in the cavity and has a first face oriented in a common direction with the first surface. The plurality of devices are disposed in the cavity and mounted on a second face of the interposer. The molded encapsulation material is disposed in the cavity and encapsulates the plurality of devices against the second face of the interposer.

In another example of the disclosure, a module having plurality of devices embedded into a thick substrate core includes an interposer having a length, width and height. A plurality of plated through holes (PTHs) in the interposer extending from a first face to a second face thereof. A plurality of devices, each device is electrically coupled to at least one solder ball attached to respective ones of the plurality of PTHs at the second face of the interposer. A molding material having a length, width and height surrounds and encapsulates the plurality of devices and solder balls, and attaches to the second face of the interposer. A structure (e.g., a substrate core) having a cavity is provided. The cavity has a first cavity portion having a length and width a little larger than the length and width of the interposer and a height a little less than the height of the interposer, and a second cavity portion having a length and width a little larger than the length and width of the encapsulation material and a height about the same as the height of the encapsulation material. End portions of the interposer are supported on a step between the first and second portions of the cavity. A gap filling material is placed in first spaces between the interposer and the first cavity portion, and to the step between the first and second cavity portions. The gap filling material is placed in second spaces between the encapsulation material and the second cavity portion, and on the step between the first and second cavity portions. A first layer of ABF lamination is disposed on the first face of the interposer and a first face of the structure. A second layer of ABF lamination is disposed on a face of the encapsulation material and a second face of the structure opposite the first face thereof.

In one example of the disclosure, a method for fabricating a plurality of modules adapted for embedding into substrate cores includes forming an interposer having a length, width and height, the height is determined by at least one redistributed layer (RDL). Forming a plurality of plated through holes (PTHs) through the at least one RDL from a first face to a second face of the interposer, the second face opposite the first face. Adding solder balls to ends of the plurality of PTHs at the second face of the interposer. Coupling a plurality of devices to the solder balls. Encapsulating the plurality of devices and solder balls with encapsulation material having a length, width and height, the encapsulation material is attached to the second face of the interposer. Forming a structure having a cavity with a first portion of a first size and a second portion of a second size, and the first size is larger than the second size. The first size of the first portion has a length and width a little larger than the length and width of the interposer, and a height a little less than the height of the interposer. The second size of the second portion has a length and width a little larger than the length and width of the encapsulation material, and a height about the same as the height of the encapsulation material. Placing the interposer with the encapsulation material attached into the cavity of the structure, and end portions of the interposer are supported on a step between the first and second portions of the cavity. Filling spaces between the interposer and the first portion of the cavity. Filling spaces between the encapsulation material and the second portion of the cavity.

In one example of the disclosure, a system in a package (SiP) having at least one module, including an interposer having a length, width and height. A plurality of plated through holes (PTHs) in the interposer extending from a first face to a second face thereof. A plurality of devices are provided. Each device is electrically coupled to at least one solder ball attached to respective ones of the plurality of PTHs at the second face of the interposer. Molding material having a length, width and height surrounds and encapsulates the plurality of devices and solder balls, and attaches to the second face of the interposer. A substrate core has a cavity with a first cavity portion having a length and width a little larger than the length and width of the interposer and a height a little less than the height of the interposer. A second cavity portion has a length and width a little larger than the length and width of the encapsulation material, and a height about the same as the height of the encapsulation material. End portions of the interposer are supported on a step between the first and second portions of the cavity. A gap filling material placed in first spaces between the interposer and the first cavity portion, and to the step between the first and second portions of the cavity. The gap filling material placed in second spaces between the encapsulation material and the second cavity portion, and to the step between the first and second portions of the cavity. A first layer of ABF lamination on the first face of the interposer and a first face of the structure. A second layer of ABF lamination on a face of the encapsulation material and a second face of the structure opposite the first face thereof.

### BRIEF DESCRIPTION OF THE DRAWINGS

So that the manner in which the above recited features of the present invention can be understood in detail, a more particular description of the invention, briefly summarized above, may be had by reference to examples, some of which are illustrated in the appended drawings. It is to be noted, however, that the appended drawings illustrate only typical examples of this invention and are therefore not to be considered limiting of its scope, for the invention may admit to other equally effective examples.

FIG. 1 illustrates a representative schematic elevational layout view of a prior art multi-layer core having a plurality of cavities, one for each embedded component device structure.

FIG. 2 illustrates a representative schematic elevational layout view of a power management module with a single core and multiple components in a cavity structure, according to an example.

FIGS. 3A, 3B, 3C and 3D illustrate representative schematic elevational layout views and process flow steps for fabricating a power management module with multiple components in a single core, according to an example.

FIGS. 4A, 4B, 4C, 4D, 4E, 4F and 4G illustrate representative schematic elevational layout views and process flow steps for fabricating the power management module with multiple components in a single core into a stepped cavity, according to an example.

FIG. 5 illustrates a representative schematic plan view of a plurality of power assemblies on a FR4 panel, according to an example.

FIG. 6 illustrates a representative schematic plan view of a system-in-package (SiP) having digital processors, memory, and a power management module, according to an example.

FIG. 7 illustrated a schematic side view of one example of an electronic device including a power management module.

FIG. 8 illustrated a schematic side view of one example of an electronic device including a power management module.

To facilitate understanding, identical reference numerals have been used, where possible, to designate identical elements that are common to the figures, and a lower-case letter added where the elements are substantially the same. It is contemplated that elements of one embodiment may be beneficially incorporated in other embodiments.

### DETAILED DESCRIPTION

An integrated circuit module is fabricated to have multiple devices clustered into an integrated assembly. This module may be created in an assembly process where the required devices and components are fabricated onto a strip of material such as, for example but not limited to, FR-4 glass-reinforced epoxy laminate material which is a composite material composed of woven fiberglass cloth with an epoxy resin binder that is flame resistant. The thickness of the strip of material, hereinafter “interposer”, may be selected, with the devices and components fabricated, to match the overall height of a substrate core.

The components and devices used in the module may be encased in a mold material where the molded area is smaller than the interposer area and is adapted for placement into a core cavity having two portions of different areas. The first portion of the cavity has an area greater than the second portion thereof. This results in a step design of the core cavity. End portions of the interposer sit on the step of the core cavity, and effectively reduces gap filing defects by reducing the required fill depths of the cavity gap spaces around the molded devices and components area, and interposer area significantly.

The process fabrication steps described hereinafter are well known and readily available. The process fabrication is a cost-effective solution to solve current issues with thick core embedding of components and devices. Clustering of multiple devices/components in a sub module fabrication flow improves substrate processing lead time of a device. Clustering of multiple devices/components in a module allows improvement in device/component density as compared to using multiple cavity formation methods. The addition of a FR4 strip helps to make up the thickness required for embedding into a thick core and also improves matching of coefficient of temperature expansion (CTE) and other modulus properties of the sub-module to the substrate core properties. The mold/substrate step design reduces effective cavity depth and thereby reduces the risk of having to do gap filling in a thick substrate core.

In the examples described hereinafter, a power management module embedded in a substrate core is shown and described. However, it is contemplated and within the scope of this disclosure that other module functions, e.g., a plurality of digital processors, a memory stack, communications module(s), e.g., WiFi, Bluetooth, LoRa, etc., may be constructed having all benefits disclosed herein, and one having ordinary skill in the art of semiconductor integrated circuit design and fabrication, and the benefit of this disclosure, could do so without undo experimentation.

A plurality of modules may be fabricated as a system in a package or system-in-package (SiP) where the SiP may comprise a power management module, a plurality of digital processors, a memory stack, and a communications module. Modules of the SiP may comprise a plurality of integrated circuits, and active and passive devices (components, e.g., resistors, capacitors, inductors, diodes, etc.). These modules may be stacked, placed side-by-side and/or embedded into a substrate. The modules of the SiP may be connected together with copper lands (conductors) embedded in the SiP substrate, and/or a plurality of substrates that may be attached and electrically connected to an interposer substrate that may also have external connections, e.g., ball grid array (BGA), pins on the SiP for further connector to an electronic system printed circuit board.

Various features are described hereinafter with reference to the drawing figures. It should be noted that the drawing figures may or may not be drawn to scale and that the elements of similar structures or functions are represented by like reference numerals throughout the drawing figures. It should be noted that the drawing figures are only intended to facilitate the description of the features of the examples. They are not intended as an exhaustive description of the examples below or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described. Referring now to the drawing figures, the details of examples are representative layouts schematically illustrated. Like elements in the drawing figures will be represented by like numbers, and similar elements will be represented by like numbers with a different lower-case letter suffix.

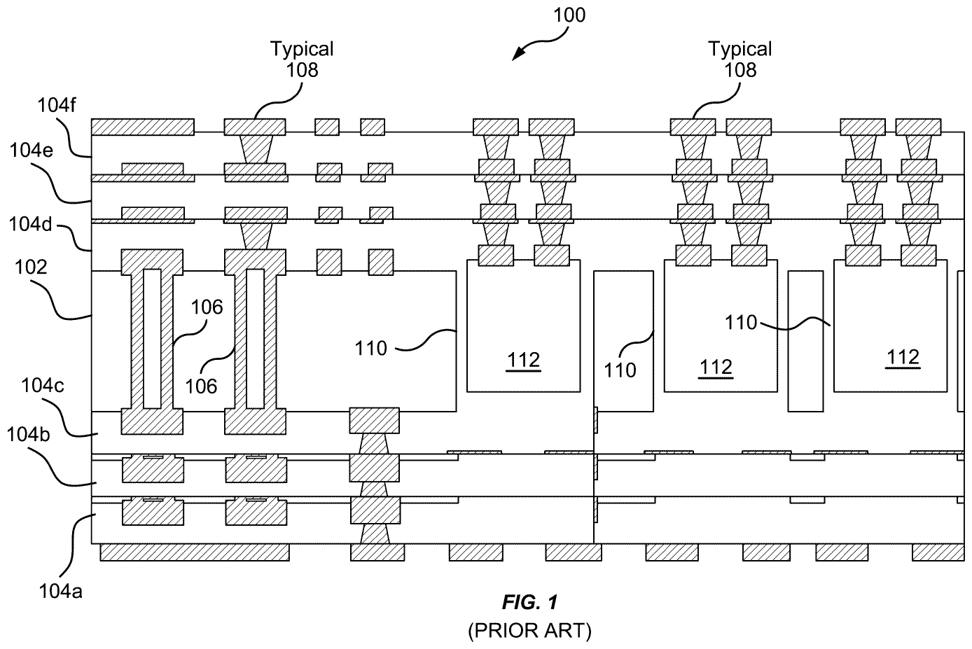

Referring to FIG. 1, depicted is a schematic elevational layout view of a prior art multi-layer core having a plurality of cavities, one for each embedded component device structure. A prior art multi-layer core having a plurality of cavities is generally represented by the numeral 100. A core layer 102 in the substrate 100 has a plurality of cavities 110 for placing components/devices therein. A plurality of redistributed layers (RDL) 104 may be used to build up the thickness of the multi-layer core 100. Copper columns 106, in the interposer 102, may connect vias 108. The vias 108 also connect to the devices 112 in the cavities 110.

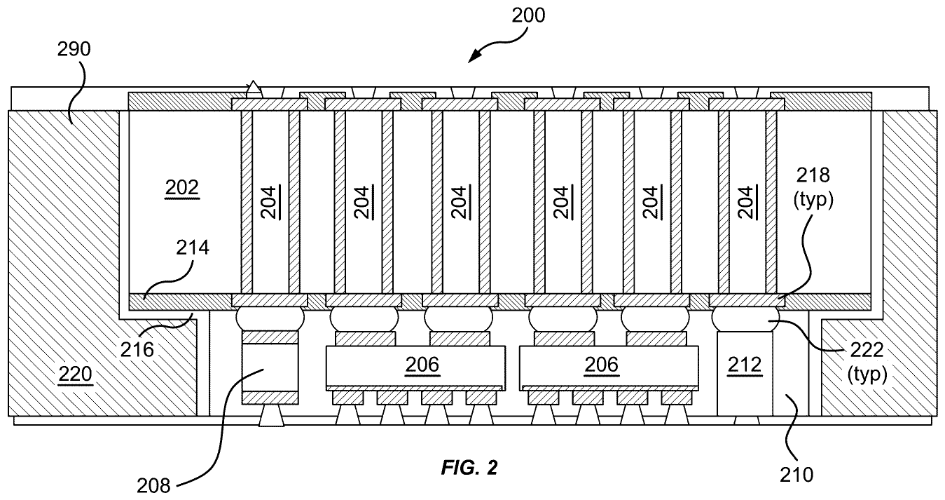

Referring to FIG. 2, depicted is a representative schematic elevational layout view of a power management module with a single core and multiple components in a cavity structure, according to an example. A power management module with a single core (e.g., substrate core 290) and multiple components in a cavity structure 220, according to the teachings of this disclosure, is generally represented by the numeral 200, and may comprise a FR4 interposer 202 with plated through holes (PTH) 204. The substrate core 290 may be fabricated from silicon, glass, or an organic substrate. The cavity structure 220 is formed completely through the substrate core 290 such that the cavity structure 220 is open to the top and bottom surfaces of the substrate core. The PTH 204 may be used for electrical connections and/or as thermal chimneys. Multiple power cell devices, e.g., integrated voltage regulators (IVR) 206a, integrated passive devices (IPD) 206b, inductors and the like; and at least one copper pin 212 are encapsulated with encapsulation material 210 to fit in a lower portion of the cavity structure 220. Between the first and second opening of the cavity structure 220 is a step 216.

A face of the FR4 interposer 202 may have at least one redistributed layer (RDL) 214 that is adapted to come into contact with the step 216. The RDL 214 comprises conductive metal patterns with a plurality of metal contacts 218. This may be accomplished with prepreg on ABF (Ajinomoto Build-up Film) if needed. Solder balls 222 may connect the power cell devices 206 and 208, and the at least one copper pin 212 to the PTH 204. The encapsulation material 210, through a transfer molding process, is used to encapsulate the assembled devices and components to the lower portion of the cavity structure 220 that is narrower than an upper portion of the lower portion of the cavity structure 220 that is narrower than an upper portion of cavity structure 220 that the FR4 interposer 202 occupies. The height of the FR4 interposer 202 is designed to occupy the remaining height in the wider upper portion of the cavity structure 220 not taken up by the height of the encapsulation material 210 surrounding the power cell devices 206 and 208, and the at least one copper pin 212.

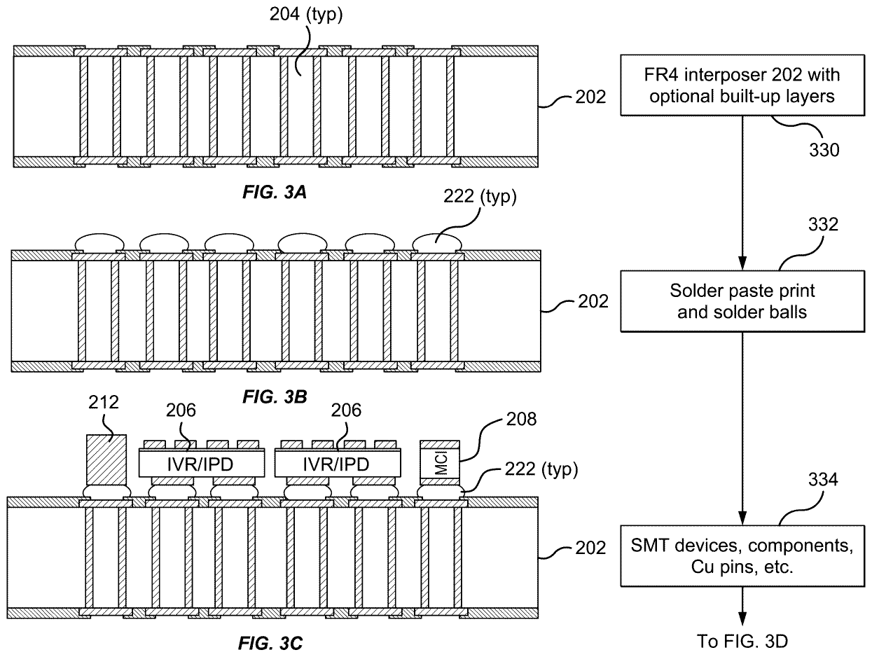

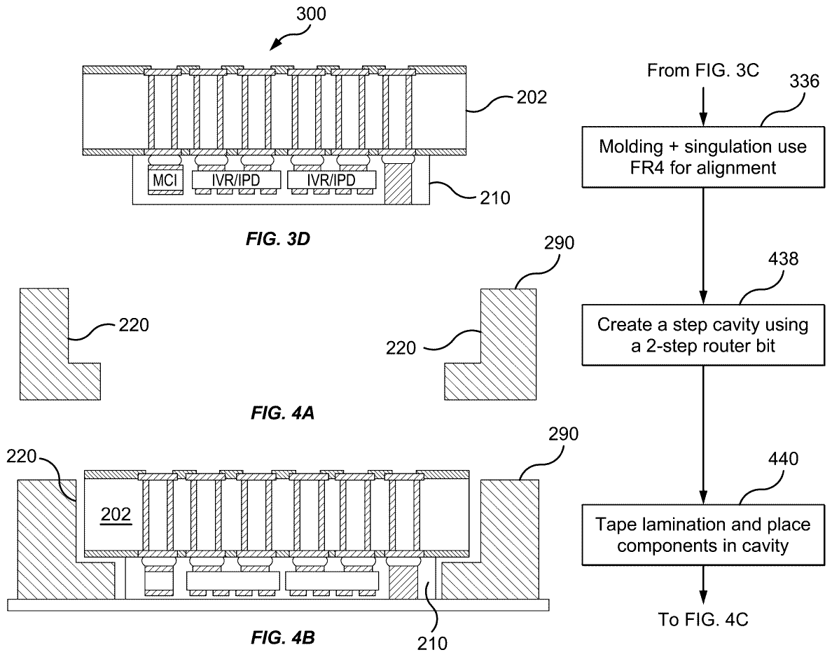

Referring to FIGS. 3A, 3B, 3C and 3D, depicted are representative schematic elevational layout views and process flow steps for fabricating a power management module with multiple components in a single core, according to an example. In step 330 (FIG. 3A), an FR4 interposer 202 with optional built-up layers may be provided with plated through holes (PTH) 204. In step 332 (FIG. 3B), solder paste is applied to ends of the PTHs 204 and solder balls 222 are placed onto the solder pasted ends of the PTHs 204. In step 334 (FIG. 3C), the power devices IVR/IPD 206 and MCI 208 and the at least one copper pin 212 are placed onto the solder balls 222 for further processing (solder reflow heating). In step 336 (FIG. 3D), encapsulation material 210 is used to encapsulate the parts placed and soldered in step 334 to create a power assembly 300 for placement into a cavity structure 220, resulting in a power management module 200.

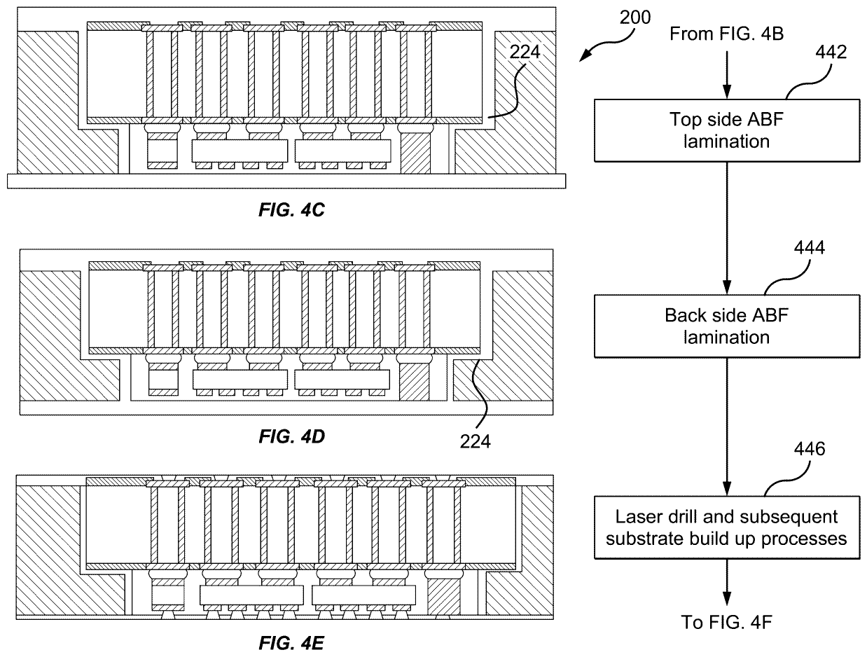

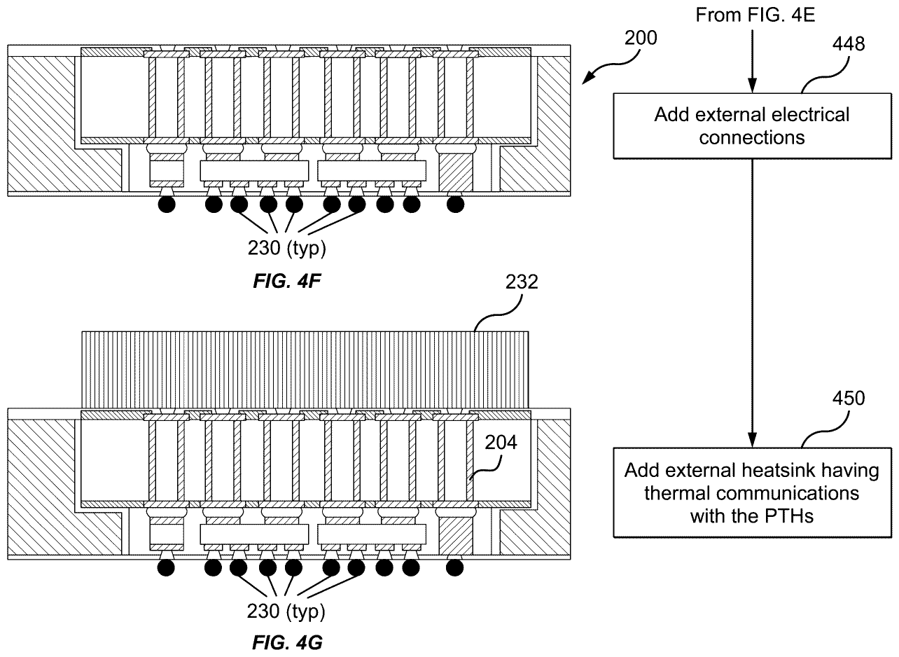

Referring to FIGS. 4A, 4B, 4C, 4D, 4E, 4F and 4G, depicted are representative schematic elevational layout views and process flow steps for fabricating the power management module with multiple components in a single core into a stepped cavity, according to an example. In step 438 (FIG. 4A), a cavity structure 220 is formed using a two-step router to create first and second portions of a cavity, where the cavity first portion has a larger inner area (length times width) than the second portion thereof. The first and second portions of the cavity structure 220 form a step 216 on which the FR4 interposer 202 is adapted to rest thereon. In step 440 (FIG. 4B), the inner area of the first portion of the cavity structure 220 is adapted to receive the outer area of the interposer 202, and the inner area of the second portion of the cavity structure 220 is adapted to receive the outer area of the encapsulation material 210. The height of the first portion of the cavity structure 220 is less than the height of the interposer 202. The height of the second portion of the cavity structure 220 is substantially the same as the height of the encapsulation material 210. The pre-assembled sub-module is placed in the cavity through a die attach film where the narrow side of the core layer may be pre-laminated to receive the sub-module.

In step 442 (FIG. 4C), a gap filling material 224 may be, for example but is not limited to, ABF, may be applied into spaces between the interposer 202 and the first portion of the cavity structure 220, and need only penetrate to the step 216. The gap between the sub-module and the cavity depends on the selected placement tool accuracy and the flowability of the gap filling material, typically not smaller than 100 micrometers. The gap filling material may also be applied over the face of the first side of the interposer 202 and the cavity structure 220. In step 444 (FIG. 4D), the gap filling material 224 may be applied from the back side of the power management module 200 and need only penetrate the space between the encapsulation material 210 and the second portion of the cavity structure 220 to the shelf or step thereof, where it preferably meets with the gap filling material 224 previously applied in step 442, or vice-versa. This two-step molding process effectively reduces gap filing risk by reducing the cavity fill distance (depth) significantly. In step 446 (FIG. 4E), the excess molding material/gap filling material is removed from the top and back sides of the power management module 200 and further processing, e.g., laser drilling and substrate build-up processes, of the power management module 200 are performed in preparation of integrating the power management module 200 into an electronics system. The spaces between and over the interposer 202, power assembly 300, and top and bottom of the cavity structure may be filled as part of the gap filling process where a portion of the gap filling material may flow to fill the gaps in the cavity and a majority portion of the material may remain on the surface. A typical process step to achieve this may be through a hot roll lamination process.

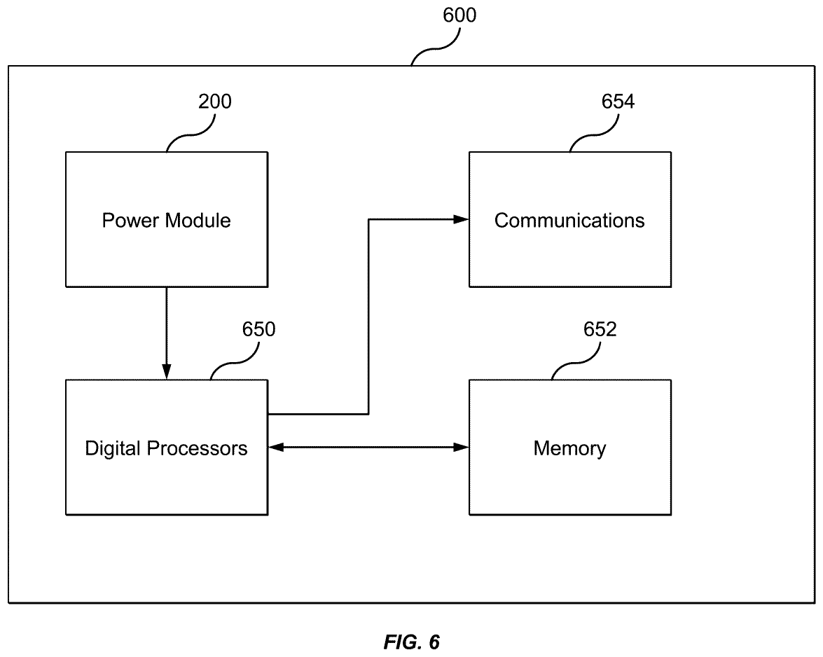

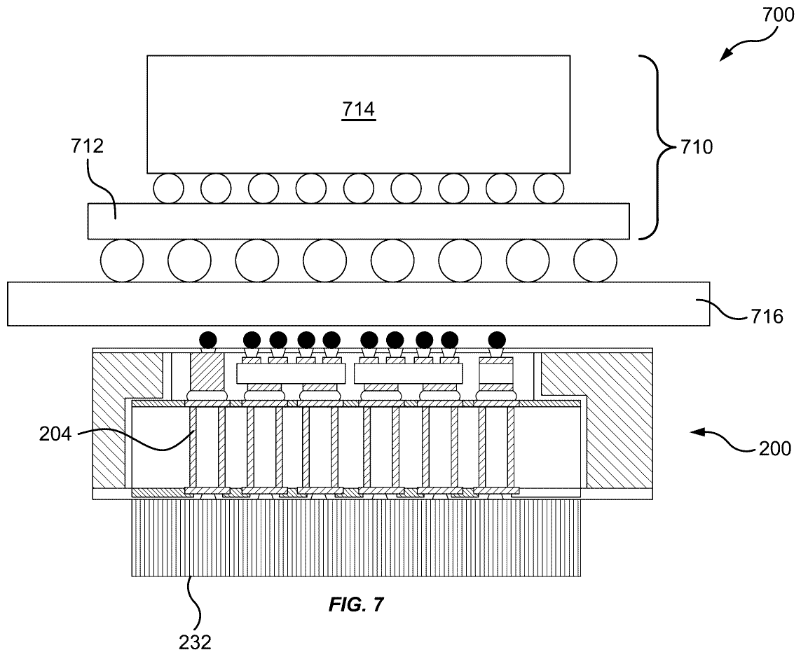

In step 448 (FIG. 4F), external connections 230 may be added to the connections from the IVR/IPD 206, MCI 208 and other components and devices (not shown) for electrically connecting these components and devices to other modules in a system-in-package (SiP) 600 (FIG. 6). These external electrical connections 230 from the module 200 may be, for example but are not limited to, ball grid array (BGA), pins, metal bonding pads, micro bumps, and the like. In step 450 (FIG. 4G), a heat sink 232 may be added to the module 200 and adapted to be in thermal communications with the thermal chimney PTHs 204.

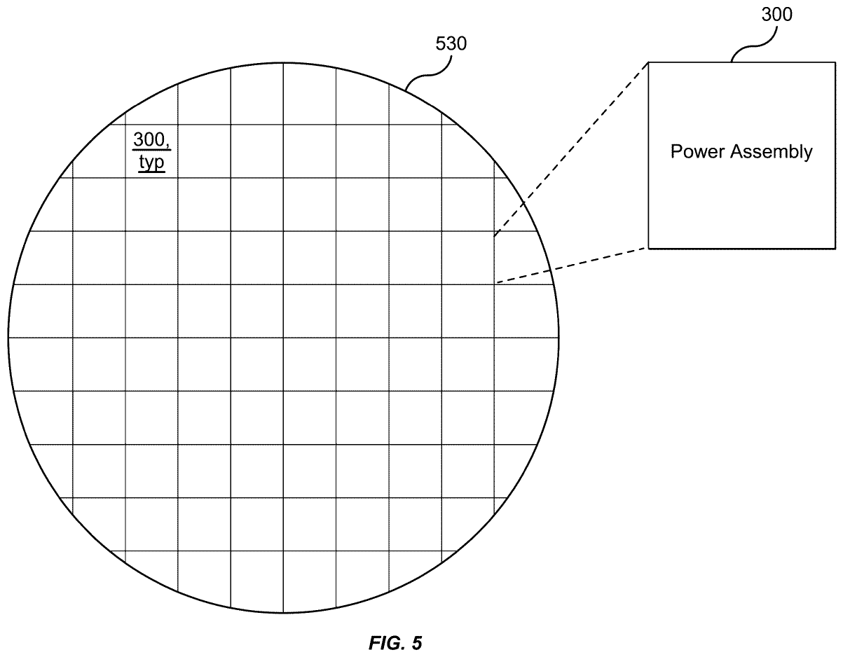

Referring to FIG. 5, depicted is a representative schematic plan view of a plurality of power assemblies on a FR4 panel, according to an example. A plurality of power assemblies 300 may be fabricated on a wafer sized substrate 530 of, for example but not limited to, FR4 material. Then separated (singulated) into individual structures after fabrication of the aforementioned power assemblies 300 thereon (FIGS. 3A-3D). The separated power assemblies 300 are now ready for adding to the cavity structures 220 (FIGS. 4A-4E), then packaging into power management modules 200 that are adapted for attachment and electrically coupling to an electronics system substrate (e.g., SiP or printed circuit board).

Referring to FIG. 6, depicted is a representative schematic plan view of a system-in-package (SiP) having digital processors, memory, and a power management module, according to an example. The SiP 600 may comprise at least one digital processor 650 receiving power from the power management module 200, a memory 652 coupled to the at least one digital processor 650 and a communications interface 654 for communicating with other digital IC packages (not shown).

For the examples disclosed above, connections between the vias (TSVs) of the active dice, interposer(s), substrate and passive pass-through dice may be done with lower resistance metal bonding pads, e.g., hybrid-bonding, copper hybrid-bonding instead of using micro bumps in the power delivery paths and may significantly lower resistance of the electrical connections. This solves a significant voltage drop problem associated with using micro bumps for electrical power circuit connections. An added benefit is elimination of the layer-to-layer (D2D) layers between the silicon wafers, allowing direct metal-to-metal electrical connections (hybrid-bonding) between layer layers, thereby further reducing the resistance of connections there between. In addition, the layer stack thickness will be reduced and heat transfer improved there-through.

FIG. 7 illustrated a schematic side view of one example of an electronic device 700 which includes a power management module 200. The electronic device 700 includes a chip package 710 mounted on a printed circuit board 716. The chip package 710 includes a least one integrated circuit (IC) die 714 mounted on a package substrate 712. The package substrate 712 of the chip package 710 is electrically and mechanically connected to a first side of the printed circuit board 716. The power management module 200 is mounted to a second side of the printed circuit board 716 below the chip package 716.

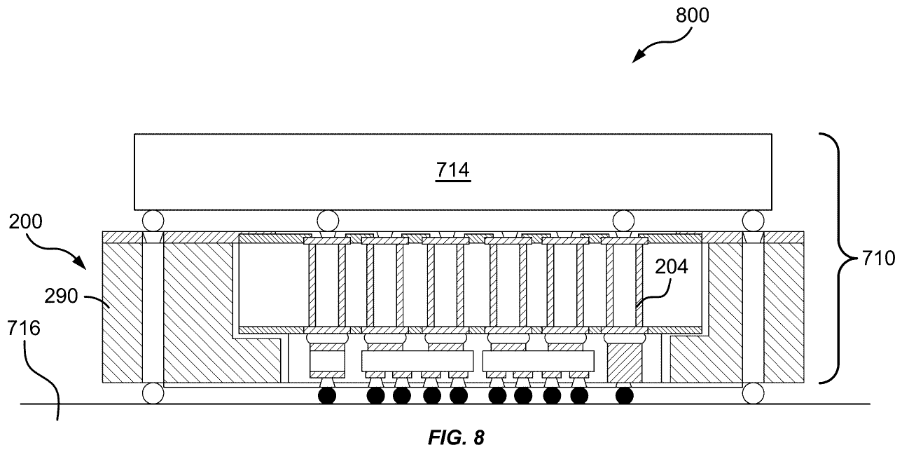

FIG. 8 illustrated a schematic side view of one example of an electronic device 800 including a power management module 200. The electronic device 800 includes a chip package 710 mounted on a printed circuit board 716. The chip package 710 includes a least one integrated circuit (IC) die 714 mounted on a package substrate 712. The package substrate 712 of the chip package 710 is electrically and mechanically connected to a first side of the printed circuit board 716. The package substrate 712 includes a power management module 200 that is disposed between the first side of the printed circuit board 716 and the IC die 714.

As will be appreciated by one skilled in the art and having the benefit of this disclosure, the embodiments disclosed herein may be embodied as a system, method, apparatus, or computer programmed product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

While the foregoing is directed to embodiments of the present invention, other and further embodiments of the invention may be devised without departing from the basic scope thereof, and the scope thereof is determined by the claims that follow.

What is claimed:

1. An integrated circuit (IC) module comprising:
a substrate core having a first face, a second face, and a cavity formed in the substrate core and open through the first and second faces of the substrate core;
an interposer disposed in the cavity and having a first face oriented in a common direction with the first surface;
a plurality of devices disposed in the cavity and mounted on a second face of the interposer; and
a molded encapsulation material disposed in the cavity and encapsulating the plurality of devices against the second face of the interposer.

2. The IC module according to claim 1, wherein the cavity further comprise a step supporting at least one of the interposer or the molded encapsulation material.

3. The IC module according to claim 1, further comprising:
a gap filling material disposed in the cavity between the interposer and substrate core, the gap filling material disposed in the cavity between the molded encapsulation material and substrate core.

4. The IC module according to claim 1, further comprising:
a first layer of ABF lamination on the first face of the interposer and the first face of the substrate core; and
a second layer of ABF lamination on a face of the molded encapsulation material and the second face of the substrate core.

5. The IC module according to claim 1, wherein the plurality of devices includes at least one power cell device.

6. The IC module according to claim 5, wherein a first device of the at least one power cell device comprises a device selected from the group consisting of a voltage regulator, a capacitor, an inductor, and a resistor.

7. The IC module according to claim 1, wherein the module is a power management module.

8. The IC module according to claim 1, wherein the interposer comprises at least one redistributed layer (RDL).

9. The IC module according to claim 1, further comprising a plurality of external electrical connections coupled to circuit and power connections of the plurality of devices.

10. The IC module according to claim 1, further comprising:
a heatsink thermally coupled a plurality of plated through holes (PTHs) formed through the interposer.

11. The IC module according to claim 1, further comprising:
a printed circuit board coupled to the module on a side of the IC module opposite the interposer.

12. The IC module according to claim 11, further comprising:
a heatsink thermally coupled to the interposer.

13. A method for fabricating an integrated circuit (IC) module, the method comprising:
electrically and mechanically mounting a plurality of devices on an interposer;
encapsulating the plurality of devices mounted on of the interposer with a molded encapsulation material to form an assembly;
inserting the assembly in a cavity extending completely through a substrate core; and
securing the assembly in the cavity to form the IC module.

14. The method according to claim 13, wherein inserting the assembly in the cavity further comprises:
supporting the assembly on a step formed on a sidewall of the cavity.

15. The method according to claim 14, wherein supporting the assembly on the step further comprises:
supporting one of the interposer or the molded encapsulation material on the step.

16. The method according to claim 13, securing the assembly in the cavity further comprises:
filling spaces between the interposer and the cavity; and
filling spaces between the molded encapsulation material and the cavity.

17. A system in a package (SiP) having at least one integrated circuit (IC) module, comprising:
a printed circuit board having a first surface and a second surface;
a chip package coupled to the first surface of the printed circuit board, the chip package having an integrated circuit (IC) mounted on a substrate; and
a power management module mounted to the second surface of the printed circuit board, the power management module comprising:
a substrate core having a first face, a second face, and a cavity formed in the substrate core and open through the first and second faces of the substrate core;
an interposer disposed in the cavity and having a first face oriented in a common direction with the first surface;
a plurality of devices disposed in the cavity and mounted on a second face of the interposer; and
a molded encapsulation material disposed in the cavity and encapsulating the plurality of devices against the second face of the interposer.

18. The SiP of claim 17, wherein the cavity of the power management module further comprises a step supporting at least one of the interposer or the molded encapsulation material.

19. The SiP according to claim 18, wherein the power management module further comprises:
a plurality of thermal chimneys formed through the interposer.

20. The SiP according to claim 19, further comprising a heatsink in thermal communications with the plurality of thermal chimneys.
